(19) United States
(12) Patent Application Publication
(10) Pub. No.: US 2025/0357213 A1
(43) Pub. Date: Nov. 20, 2025

(54) METHOD FOR FORMING A SEMICONDUCTOR DIE

(71) Applicant: Infineon Technologies Austria AG, Villach (AT)

(72) Inventors: Sanja Radosavljevic, Villach (AT); Sylvain Leomant, Pörtschach am Wörther See (AT); Rajeev Krishna Vytla, Villach (AT)

(21) Appl. No.: 19/206,645

(22) Filed: May 13, 2025

(30) Foreign Application Priority Data
May 14, 2024 (DE) 102024113452.6

(51) Int. Cl. H01L 21/78; H01L 21/762

(52) U.S. Cl. CPC H01L 21/78; H01L 21/76224

(57) ABSTRACT

A method and a semiconductor die are disclosed. The method includes forming a semiconductor die based on a wafer. The wafer includes a semiconductor layer and a sacrificial layer formed on opposite sides of an insulating layer. The method includes: forming a separation structure that includes a separation trench laterally surrounding a die region in the first semiconductor layer of the wafer and that vertically extends from a first surface of the wafer through the semiconductor layer to the insulating layer of the wafer; removing the sacrificial layer; and detaching the die region along the separation structure to separate the semiconductor die from the wafer.

### TECHNICAL FIELD

This disclosure relates in general to a method for forming a semiconductor die.

### BACKGROUND

A semiconductor die is a piece of semiconductor that was separated from a semiconductor wafer. Usually, semiconductor dies are separated from a wafer by a cutting process.

A semiconductor die may include one or more semiconductor devices integrated therein. A vertical semiconductor device, such as a vertical transistor, is a device that has load terminals, such as source and drain terminals in a vertical transistor, on opposite sides of the die, so that a load current path of the semiconductor device extends in a vertical direction through the semiconductor die.

With a vertical semiconductor device, a thickness of the die, which is the dimension of the die in the vertical direction, has a significant impact on the electrical resistance of the load current path. It is therefore desirable to precisely adjust the thickness of the die. Conventional methods for adjusting the die thickness include thinning the wafer using etching or grinding processes, for example, before separating the wafer to form the individual semiconductor dies. Such etching or grinding processes, however, are subject to fluctuations so that the die thickness cannot always be adjusted with the desired accuracy.

There is therefore a need for a process for producing a semiconductor die with a desired thickness.

### SUMMARY

One example relates to a method for forming a semiconductor die based on a wafer. The wafer includes a semiconductor layer and a sacrificial layer formed on opposite sides of an insulating layer. The method includes forming a separation structure that includes a separation trench laterally surrounding a die region in the semiconductor layer of the wafer and that vertically extends from a first surface through the semiconductor layer to the insulating layer of the wafer. The method further includes removing the sacrificial layer, and detaching the die region along the separation structure to separate the semiconductor die from the wafer.

Another example relates to a semiconductor die having a shape different from a rectangular shape.

### BRIEF DESCRIPTION OF THE DRAWINGS

Examples are explained below with reference to the drawings. The drawings serve to illustrate certain principles, so that only aspects necessary for understanding these principles are illustrated. The drawings are not to scale. In the drawings the same reference characters denote like features.

FIG. 1 illustrates a vertical cross-sectional view of a wafer that includes a semiconductor layer and a sacrificial layer arranged on opposite sides of an insulating layer;

FIG. 2 illustrates one example of a method for forming a semiconductor die based on a wafer illustrated in FIG. 1;

FIGS. 3A and 3B illustrate a portion of a semiconductor wafer of the type illustrated in FIG. 1 after forming a separation structure that surrounds a die region;

FIGS. 4A-4C schematically illustrate top views of semiconductor wafers according to different examples, each including a plurality of die regions surrounded by a separation structure;

FIG. 5 illustrates the portion of the wafer illustrated in FIG. 3A after removing the sacrificial layer;

FIG. 6 illustrates the portion of the wafer illustrated in FIG. 5 during a process of detaching the die region;

FIGS. 7A-7C illustrate one example of a method for forming the separation structure;

FIG. 8 schematically illustrates a die region having a lateral transistor device integrated therein;

FIG. 9 schematically illustrates a die region having a the vertical transistor device integrated therein;

FIGS. 10A-10B illustrate one example of a method for forming a load path electrode of the vertical transistor device;

FIG. 11 illustrates one example of a method for forming a doped region of the vertical transistor device;

FIGS. 12A-12B illustrate one example of a vertical transistor device in greater detail;

FIGS. 13A-13B illustrate a portion of a wafer of the type illustrated in FIG. 1 after forming a separation structure and an isolation structure;

FIGS. 14A-14B illustrate different modifications of the isolation structure illustrated in FIG. 13B;

FIG. 15 schematically illustrates a vertical cross-sectional view of one portion of the wafer after removing the second semiconductor layer and forming electrodes of semiconductor devices integrated in different isolated regions;

FIGS. 16A-16D illustrate one example of a method for forming a separation structure and an isolation structure based on common process steps; and

FIG. 17A-17D illustrates a top view of a semiconductor die according to different examples.

### DETAILED DESCRIPTION

In the following detailed description, reference is made to the accompanying drawings. The drawings form a part of the description and for the purpose of illustration show examples of how the invention may be used and implemented. It is to be understood that the features of the various embodiments described herein may be combined with each other, unless specifically noted otherwise.

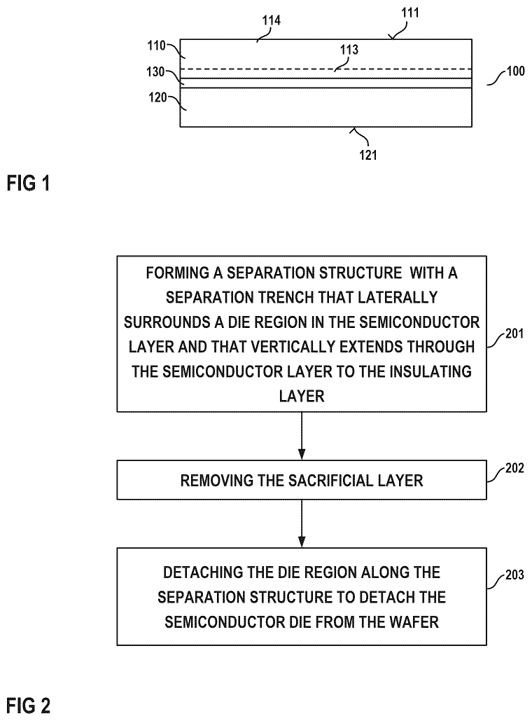

FIG. 1 shows a vertical cross-sectional view of a wafer 100 based on which at least one semiconductor die can be formed. The wafer 100 includes a semiconductor layer 110 and a sacrificial layer 120 that are formed on opposite sides of an insulating layer 130.

According to one example, the semiconductor layer 110 includes a monocrystalline semiconductor material. Examples of the monocrystalline semiconductor material include, but are not restricted to, silicon (Si), silicon carbide (SiC), gallium arsenide (GaAs), gallium nitride (GaN), or indium phosphide (InP), for example

According to one example, the sacrificial layer 120 is a semiconductor layer. According to one example, the sacrificial layer 120 includes a monocrystalline semiconductor material. Examples of the monocrystalline semiconductor material include, but are not restricted to, silicon (Si), silicon carbide (SiC), gallium arsenide (GaAs), gallium nitride (GaN), or indium phosphide (InP), for example. The semiconductor layer 110 and the sacrificial layer 120 may include the same type of monocrystalline semiconductor material, or may include different types of monocrystalline semiconductor materials.

According to another example, the semiconductor layer 110 includes a monocrystalline semiconductor material, such as one of the monocrystalline semiconductor materials explained herein before, and the sacrificial layer 120 includes a polycrystalline semiconductor material. The polycrystalline semiconductor material is polysilicon, for example.

According to one example, the insulating layer 130 separating the semiconductor layer 110 and the sacrificial layer 120 includes an oxide. According to one example, the oxide is a semiconductor oxide. According to one example, the semiconductor oxide is an oxide of the semiconductor material of the semiconductor layer 110 or of the sacrificial layer 120, when the sacrificial layer is a semiconductor layer. According to one example, the insulating layer 130 includes silicon dioxide (SiO₂).

A thickness of the insulating layer 130 is selected from a range of between 100 nanometers (nm) and 5 micrometers (μm), in particular between 1 μm and 3 μm, for example. The thickness of the insulating layer 130 is a dimension of the insulating layer 130 in a vertical direction of the wafer 100. The vertical direction of the wafer 100 is a direction that is essentially perpendicular to a first and second surfaces 111, 121 of the wafer 100. The first surface 111 of the wafer 100 is formed by a surface of the semiconductor layer 110 that faces away from the insulating layer 130, and the second surface 121 of the wafer 100 is formed by a surface of the sacrificial layer 120 that faces away from the insulating layer 130.

A thickness of the semiconductor layer 110 is selected from a range of between 50 nm and 20 μm, in particular between 2 μm and 25 μm, for example. The thickness of the semiconductor layer 110 is the dimension of the semiconductor layer 110 in the vertical direction of the wafer 100. As explained herein further below, at least one semiconductor device may be integrated in the semiconductor layer 110. The thickness of the semiconductor layer 110 may be selected dependent on the type and the desired properties of the semiconductor device to be integrated in the semiconductor layer 110.

A thickness of the sacrificial layer 120 is selected from a range of between 50 μm and 1500 μm, in particular between 600 μm and 1200 μm, for example.

According to one example illustrated in dashed lines in FIG. 1, the semiconductor layer 110 includes a first sub-layer 113 adjoining the insulating layer 130, and a second sub-layer 114 formed on top of the first sub-layer 113. According to one example, the second sub-layer 114 is an epitaxial layer formed on top of the first sub-layer 113. According to one example, the first sub-layer 113 has a thickness lower than 1 μm, lower than 0.5 μm (500 nm), or even lower than 0.1 μm (100 nm) and the desired overall thickness of the semiconductor layer 110 is adjusted by adjusting the thickness of the epitaxial layer 113 in an epitaxial growth process for forming the second sub-layer 114. In this example, the same type of wafer precursor that includes the sacrificial layer 120, the insulating layer 130, and the first sub-layer 113 can be produced for various kinds of applications. Based on one of the wafer precursors, a wafer 100 for a specific application can then be produced by forming the epitaxial layer 113 with the desired thickness on top of the first sub-layer 112.

Referring to the above, at least one semiconductor die can be formed based on the wafer 100 illustrated in FIG. 1. One example of a method for producing a semiconductor die based on the wafer 100 is illustrated in FIG. 2.

Referring to FIG. 2, the method includes (201) forming a separation structure with a separation trench that laterally surrounds a die region in the semiconductor layer and that vertically extends through the semiconductor layer to the insulating layer; (202) removing the sacrificial layer; and (203) detaching the die region along the separation structure to form and detach the semiconductor die from the wafer.

Examples of the method illustrated in FIG. 2 are explained in the following with reference to further figures.

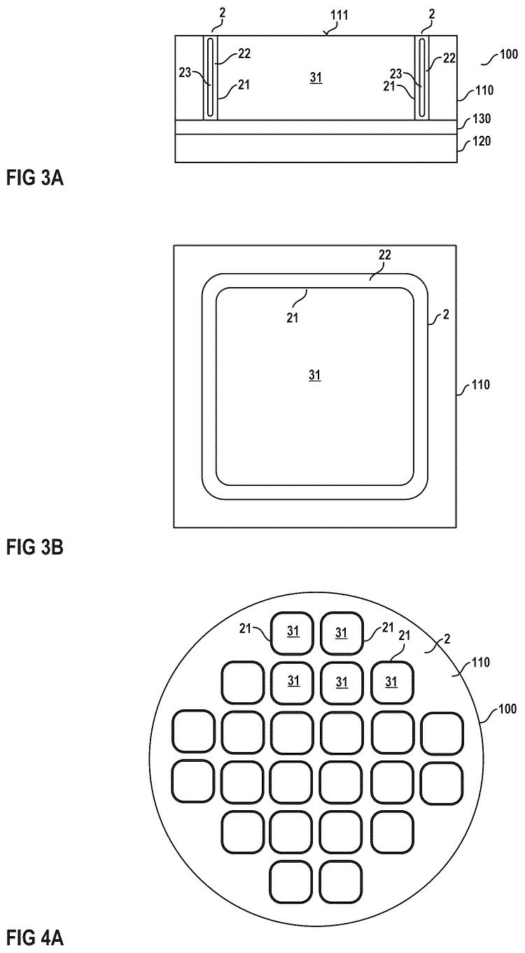

FIGS. 3A-3B illustrate one example of the semiconductor layer 110 after forming a separation structure 2 with a separation trench 21. FIG. 3A shows a vertical cross-sectional view of one portion of the wafer 100. More specifically, FIG. 3A shows a vertical cross sectional view of one portion of the semiconductor layer 110 that includes a die region 31 and a separation structure 2 surrounding the die region, a portion of the insulating layer 130 adjoining the illustrated portion of the semiconductor layer semiconductor layer 110, and a portion of the sacrificial layer 120 adjoining the illustrated portion of the insulating layer 130. FIG. 3B shows a top view of the semiconductor layer 110 and the separation structure 2 with the separation trench 21 laterally surrounding the die region 31 in the semiconductor layer 110. “Laterally surrounding” includes surrounding in lateral directions, which are directions that are essentially parallel to the first and second surfaces 111, 121 of the wafer 100.

In the example illustrated in FIG. 3B, the separation trench 21 is essentially rectangular with rounded corners. This, however, is only an example. The separation trench 21 is not restricted to be rectangular, but can be implemented with a variety of different geometrical shapes. Further examples are explained herein further below.

Referring to FIGS. 3A-3B, the separation structure 2 may further include a dielectric layer 22 covering sidewalls and a bottom of the separation trench 21, and a void 23 enclosed by the dielectric layer 22. According to one example, the dielectric layer 22 is a single layer of the same material. According to another example, the dielectric layer 22 is a layer stack that includes two or more sub-layers of different dielectric materials. According to one example, the dielectric layer 22 includes at least one of an oxide, such as silicon oxide, and a nitride, such as silicon nitride.

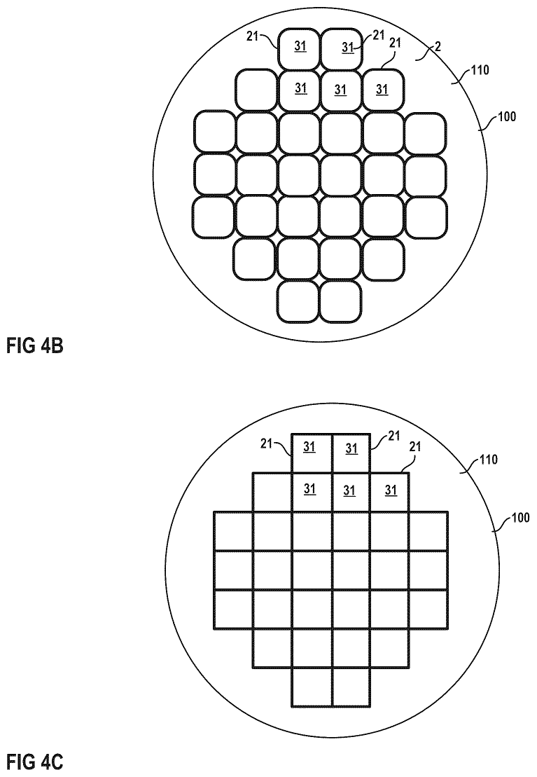

FIGS. 4A-4C show top views of the overall wafer 100 according to different examples after forming a separation structure 2 with several separation trenches 21 that each surround a respective die region 31. The separation trenches 21 are illustrated in bold lines in FIGS. 4A-4C.

According to one example illustrated in FIG. 4A, the individual separation trenches 21 are spaced apart from each other, so that portions of the semiconductor layer 110 remain between the individual separation trenches 21. The portions of the semiconductor layer 110 remaining between the individual separation trenches 21 may be referred to as kerf. The kerf may remain after detaching the individual die regions 31 along the separation trenches 21 from the wafer 100.

According to further examples illustrated in FIGS. 4B-4C, the separation trenches 21 of the separation structure 2 form a grid, wherein grid openings define a plurality of die regions 31. In the example illustrated in FIG. 4B, the die regions 31 are essentially rectangular with rounded corners. In this example, adjacent to corners of neighboring die regions 31 pile-shaped portion of the semiconductor layer 110 remain outside the die regions 31 and may remain after detaching the die regions 31 from the wafer.

In the example illustrated in FIG. 4C, the die regions 31 are essentially rectangular with sharp corners.

As compared to the example illustrated in FIG. 4A, the examples illustrated in FIG. 4B and 4C are more efficient in terms of space consumption and lead to a higher yield with a given wafer size.

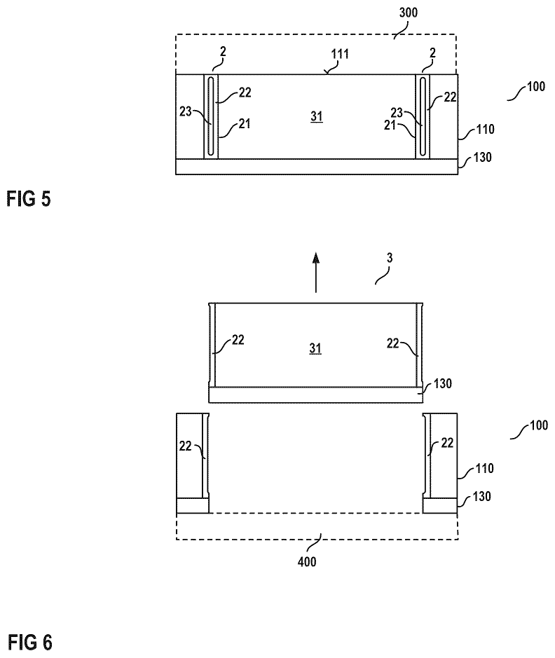

FIG. 5 shows the arrangement illustrated in FIGS. 3A-3B after removing the sacrificial layer 120. According to one example, in the process of removing the sacrificial layer 120, the insulating layer 130 acts as a stop layer which is not or which is at most partially removed. This is illustrated in FIG. 5. According to another example (not illustrated), the insulating layer 130 is completely removed after removing the sacrificial layer 120.

Removing the sacrificial layer 120 may include any type of process that is suitable for removing the sacrificial layer 120 from on top of the insulating layer 130. Examples of the removing process include, but are not restricted to, an etching process, a mechanical polishing process, a chemically-mechanical polishing (CMP) process, or a combination of two or more of these processes.

According to one example illustrated in dashed lines in FIG. 5, a carrier 300 is mounted to the first surface 111 before the process of removing the sacrificial layer 120.

It should be noted that “mounting the carriers 300 to the first surface 111” may include directly mounting the carrier 300 to the first surface 111, or mounting the carrier 302 to a layer or layer stack formed on top of the first surface 111. Such layer or a layer stack may include one or more metal layers and/or, one or more dielectric layers. The carrier 300 provides for a mechanical stability of the wafer during the removal process, for example. Any type of carrier 300 that is suitable for stabilizing the wafer can be used. According to one example, the carrier 300 is a glass carrier.

FIG. 6 illustrates the arrangement illustrated in FIG. 5 in the process of detaching the die region 31 from the wafer 100 to separate the die region 31 from the remainder of the wafer 100 and thereby form the semiconductor die 3. In addition to the die region 31 the semiconductor die 3 may further include portions of the insulating layer 130 and portions of the dielectric layer 22 previously included in the separation trench 21. According to one example, the portions of the dielectric layer 22 remaining at sidewalls of the die region 31 form a passivation layer that laterally surrounds the semiconductor die 3. The sidewalls of the die region 31 are formed by sidewalls of the separation trench 21 before detaching the die region 31 from the remainder of the wafer 100.

Referring to the above, a carrier 300 may be mounted to the first surface 111 during the process of removing the sacrificial layer 120. According to one example, the carrier 300 is removed before detaching the die region 31 from the wafer 100.

According to one example, after the process of removing the sacrificial layer 120 and before the detaching process, the wafer 100 is placed on a carrier 400 such that the first surface 111 faces away from the carrier 400. In the example illustrated in FIGS. 5 and 6, the insulating layer 130 has not been completely removed after removing the sacrificial layer 120. In this example, the insulating layer 130 faces the carrier 400 and the carrier 400 is mounted to the insulating layer 130. In another example (not illustrated) in which the insulating layer 130 is completely removed after removing the sacrificial layer 120, the carrier 400 is directly mounted to a surface of the semiconductor layer 110 facing away from the first surface 111. The carrier 400 is a flexible carrier, such as foil, for example, and stabilizes the wafer during that detaching process.

The die region 31 can be detached from the remainder of the wafer 100 in various ways.

According to one example, a lifting tool or pick-and-placed tool, such as a vacuum tool, is brought in contact with the die region 31 at the first surface 111 of the wafer. Using the lifting tool, the die region 31 is pulled away from the wafer 100. The force exerted by the lifting tool causes the dielectric layer 22 to break at the bottom and top of the separation trench 21, and causes the insulating layer 130 to break below the separation trench 21. Such a breaking of the dielectric layer 22 and the insulating layer 130 makes it possible to detach the die region 31 from the remainder of the wafer 100. If the wafer 100 is placed on the carrier 400, the lifting tool, in addition to breaking the dielectric layer 22 and the insulating layer 130 lifts off the semiconductor die 3 from the carrier 400.

According to another example, for detaching the semiconductor die 3 from the wafer 100, a force is exerted on the insulating layer 130 on a side opposite the first surface 111 in order to push the die region 31 away from the remainder of the wafer 100. If the wafer is placed on the carrier 400, the pushing force is applied to the insulating layer 130 through the carrier 400. The pushing force may be applied by a pushing tool. The exerted pushing force causes the dielectric layer 22 to break at the bottom and top of the separation trench 21, and causes the insulating layer 132 to break below the separation trench 21 and makes it possible to detach the die region 31 from the remainder of the wafer 100.

The method explained before makes it possible to produce a semiconductor die 3 with a well-defined thickness of the semiconductor layer included in the semiconductor die 3. The thickness of the semiconductor layer included in the die 3 is defined by the thickness of the semiconductor layer 110 of the wafer 100. Referring to the above, the thickness of the semiconductor layer 110 can be exactly adjusted, in the process of producing the wafer 100.

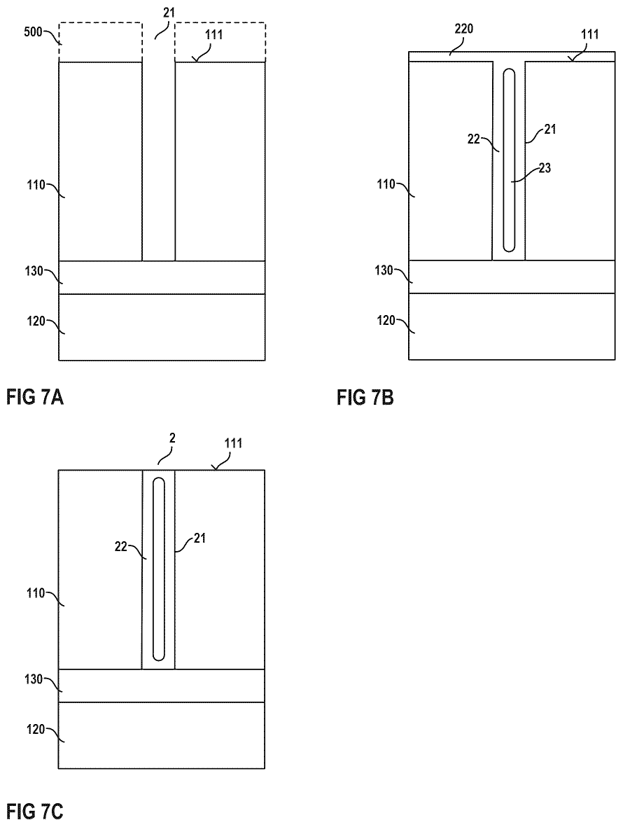

Referring to the above, the separation structure 2 may include a dielectric layer 22 and a void 23 enclosed by the dielectric layer 22. One example of a method for forming a separation structure 2 of this type is explained with reference to FIGS. 7A-7C in the following. Each of FIGS. 7A-7C shows a vertical cross-sectional view of one portion of the semiconductor wafer 100 in which the separation trench 21 with the dielectric layer 22 and the void 23 is formed.

Referring to FIG. 7A, the method includes forming the separation trench 21 that extends from the first surface 111 down to the insulating layer 130. According to one example, forming the separation trench 21 includes an etching process, such as an anisotropic etching process, using an etch mask 560 (illustrated in dashed lines) formed on top of the first surface 111. According to one example, etching the semiconductor layer 110 to form the separation trench 21 includes etching the semiconductor layer 110 selectively relative to the insulating layer 130, so that the etching process stops at the insulating layer 130 and the separation trench 21 is etched down to the insulating layer 130, but not into the insulating layer 130.

A depth of the separation trench 21, which is a dimension of the separation trench in the vertical direction of the wafer, is defined by the thickness of the semiconductor layer 110. A width of the separation trench 21, which is a shortest lateral dimension of the separation trench 21, is between 0.5 μm and 2 μm, for example. According to one example, an aspect ratio of the separation trench, which is a ratio between the trench width and the trench depth, is between 1:25 and 1:50, for example. According to one example, the separation trench 21 has tapered sidewalls such that the separation trench 21 narrows towards the trench bottom. According to another example, the separation trench 21 has paper sidewalls such that the separation trench 21 widens towards the trench bottom. In both cases, the trench width explained above relates to an average trench width.

Referring to FIG. 7B, the method further includes forming a dielectric layer 220 on top of the first surface 111, along sidewalls of the separation trench and at the bottom of the separation trench. According to one example, forming the dielectric layer 220 includes a deposition process in which the dielectric layer 220 is deposited. Inside the separation trench 21 the deposited dielectric layer 220 forms the dielectric layer 22 explained above that encloses the void 23. The void 23 is automatically formed during the deposition process. Forming the void 23 can be supported by suitably selecting process parameter is in the deposition process. Mainly, however, forming the void is supported by having a narrow trench. Furthermore, a trench supporting the formation of a void may have sharp corners between sidewalls and the first surface 111, and sidewalls that are essentially perpendicular to the first surface 111 (non-tapered). According to one example, a narrow trench is a trench having a trench width of below 3 μm, in particular below 2 μm, in particular below 1.5 μm. With a narrow trench, an upper portion of the separation trench 21 is entirely filled by the dielectric layer 222 to form a plug on top of the void 23 before the separation trench 21 can entirely be filled by the dielectric layer 220.

Due to the void 23 the die region 31 (see, e.g., FIGS. 5 and 6) is connected to the remainder of the wafer 100 only through portions of the dielectric layer 22 at the trench bottom and the top of the separation trench 21 and through the insulating layer 130. These portions of the dielectric layer 22 at the trench bottom and the top of the trench and the insulating layer 130 easily break by exerting a pulling or pushing force on the die region 31 as explained above.

According to one example illustrated in FIG. 7C, the dielectric layer 220 is removed from the first surface 111, so that only the dielectric layer 22 enclosing the void 23 remains in the separation trench 21. Removing the dielectric layer 220 from the first surface 110 may include any kind of removal process such as, for example, a mechanical polishing process, a CMP process, an etching process, or a combination of two or more of these processes.

Referring to the above, at least one semiconductor device may be formed in the die region 31 before the die region 31 is removed from the wafer 100. Any type of semiconductor device may be implemented in the die region 31.

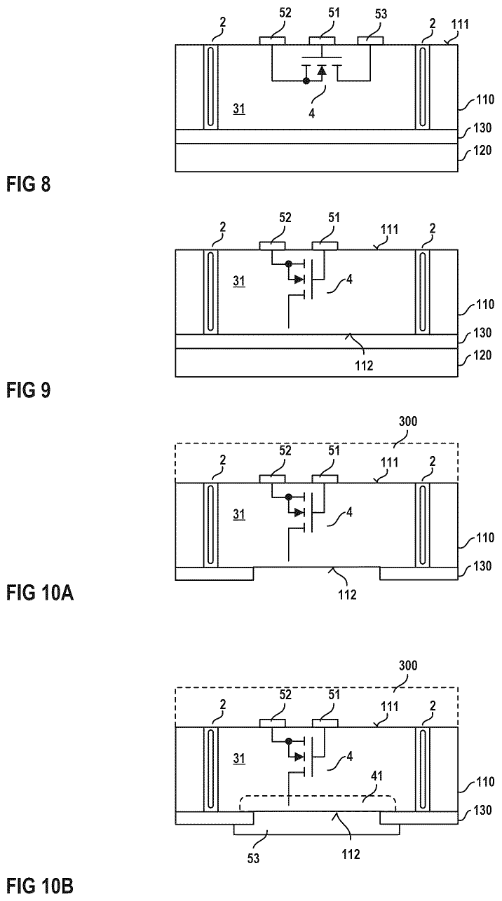

According to one example, the semiconductor device is a transistor device. One example of a transistor device integrated in the die region 31 is illustrated in FIG. 8, which schematically illustrates a vertical cross-sectional view of one die region 31.

The transistor device illustrated in FIG. 8 is a lateral transistor device. The transistor device includes a control node connected to a control terminal 51 formed above the first surface 111 and first and second load nodes each connected to a respective load terminal 52, 53 formed above the first surface 111. In the example illustrated in FIG. 8, the transistor device is represented by its circuit symbol, device regions of the transistor device are not illustrated in detail in FIG. 8. Just for the purpose of illustration, the transistor device illustrated in FIG. 8 is a MOSFET (Metal Oxide Semiconductor Field-Effect Transistor). In this example, the control node is a gate node, and the first and second load path nodes are drain and source nodes of the MOSFET.

The circuit symbol illustrated in FIG. 8 represents an N-type enhancement MOSFET. The transistor device, implemented in the die region 31, however, is not restricted to being implemented as a specific type of transistor device. Instead, any type of transistor device, in particular any type of MOSFET, may be integrated in the die region 31. Further examples of transistor devices that can be implemented in the die region 31 include, but are not restricted to, IGBTs (Insulated Gate Bipolar Transistors), JFETs (Junction Field-Effect Transistors), or BJTs (Bipolar Junction Transistors).

Alternatively or in addition to a transistor device at least one passive device, such as a resistor or capacitor may be integrated in the die region 31.

A lateral device, such as the lateral transistor device 4 illustrated in FIG. 8, may entirely be formed in the die region 31 before performing any of the process sequences explained hereinabove that include removing the sacrificial layer 120 and detaching the die region 31 from the wafer 100.

According to another example illustrated in FIG. 9, the transistor device 4 is a vertical transistor device. In this example, the control node, such as a gate node of a MOSFET, is connected to a control terminal 51 above the first surface 111 and a first load path node, such as a source node of a MOSFET, is connected to a first load terminal 52 above the first surface 111. Referring to the above, the first surface 111 of the wafer is formed by a first surface of the semiconductor layer 110. In a vertical transistor device, first and second load path terminals, such as source and drain terminals of a MOSFET, may be arranged on opposite sides of a semiconductor die. Thus, in the example illustrated in FIG. 9, a second load terminal of the transistor device, such as a drain terminal of a MOSFET, is to be formed on a second surface 112 of the semiconductor layer 110. The second surface 112 is opposite the first surface 111 and faces the insulating layer 130.

FIG. 9 illustrates a portion of the wafer 100 before removing the sacrificial layer 120. In this state of the manufacturing process, the vertical transistor device is not yet complete, as at least the second load terminal could not yet be produced because of the insulating layer 130 covering the second surface 112 and the sacrificial layer 120 covering the insulating layer 130.

One example of a method for finishing the vertical transistor device 4 illustrated in FIG. 9 is illustrated in FIGS. 10A-10B. Each of these figures shows the arrangement illustrated in FIG. 9 after certain process sequences.

Referring to FIG. 10A, the method includes removing the sacrificial layer 120 from above the insulating layer 130 and either removing the insulating layer 130, as explained above, or forming an opening in the insulating layer 130 to uncover a portion of the second surface 112 adjacent to the die region 31. The sacrificial layer 120 can be removed by a method in accordance with any of the examples explained herein above. Forming the opening in the insulating layer 130 may include an etching process that etches the insulating layer 130 selectively relative to the semiconductor layer 110. The etching process may include forming an etch mask (not illustrated) on top of the insulating layer 130, wherein the etch mask covers those portions of the insulating layer 130 that remain after the etching process.

According to one example, forming the opening in the insulating layer 130 includes forming the opening such that the insulating layer remains at least adjacent to the separation structure 2, that is, adjacent to the separation trench 21.

Referring to FIG. 10B, the method further includes forming the second load terminal 53 on the second surface 112 adjacent to the die region 31. Forming the second load terminal 53 may include depositing an electrode layer and patterning the electrode layer in an etching process. The electrode layer is an electrically conducting layer, such as a metal layer. This type of process is commonly known, so that no further explanation is required in this regard.

Referring to FIGS. 10A-10B, the carrier 300 may be formed above the first surface 111 of the semiconductor layer 110 before removing the sacrificial layer 120. The carrier 300 may remain in place during the process of removing the sacrificial layer, forming the opening in the insulating layer 130, and forming the second load terminal 53.

According to one example illustrated in FIG. 11, before forming the second load terminal 53, dopant atoms are implanted into the die region 31 through uncovered portions of the first surface 112 to form a device region 41 of the transistor device 4. According to one example, the device region 41 is a drain region of the transistor device. In addition to implanting dopant atoms, forming the device region 41 may include an annealing process in which the implanted dopant atoms are activated. According to one example, the second load terminal 53 is formed to contact the device region 41. The optional device region 41 is illustrated in dashed lines in FIG. 10B.

According to one example, in the implantation process for forming the device region 41, the insulating layer 130 acts as an implantation mask that prevents dopant atoms from being implanted into those regions of the semiconductor layer 110 that are covered by the insulating layer 130. According to another example, an implantation mask (not illustrated) is formed on top of the insulating layer 130 and, optionally, on portions of the second surface 112 before the implantation process. In this example, the implantation mask covers those regions into which dopant atoms are not to be implanted.

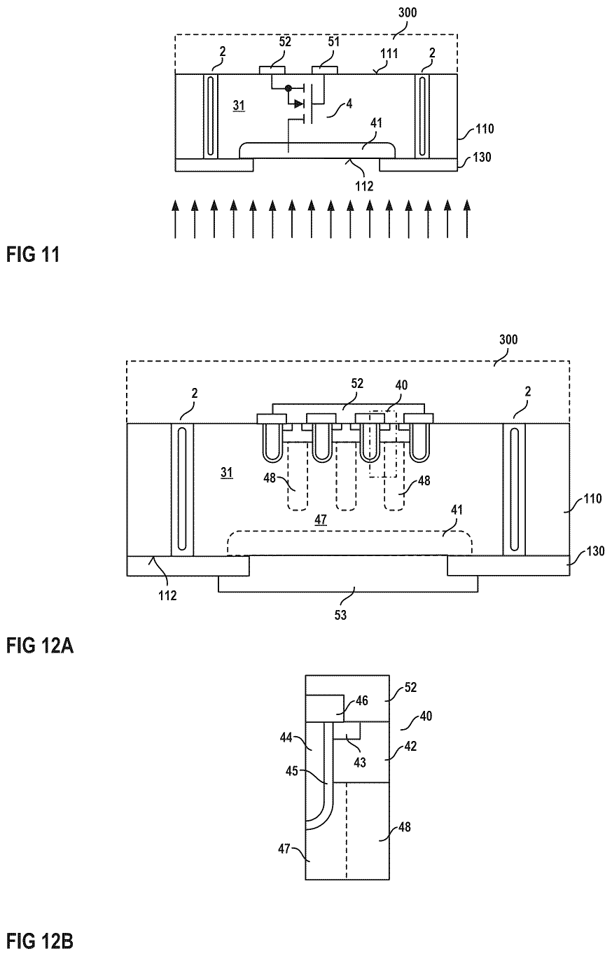

One detailed example of a vertical transistor device, in particular, a vertical MOSFET, is illustrated in FIGS. 12A-12B. FIG. 12A illustrates a vertical cross-sectional view of a die region 31 in which the vertical transistor device is integrated. The transistor device includes a plurality of transistor cells 40. FIG. 12B illustrates one transistor cell 40 in detail.

Referring to FIG. 12B, each transistor cell 40 includes a source region 43 of a first doping type and a body region 42 of a second doping type complementary to the first doping type. The body region 42 is arranged between the source region 43 and a drift region 47 of the first doping type. According to one example, the drift region 47 of the transistor device is formed by one contiguous doped region of the first doping type. Each transistor cell 40 further includes a gate electrode 44 arranged adjacent to the body region 42 and dielectrically insulated from the body region 42 by a gate dielectric 45. In a conventional way, the gate electrode 44 is configured to control a conducting channel in the body region 42 between the source region 43 and the drift region 47.

In the example illustrated in FIGS. 12A-12B, the gate electrode 44 is a trench electrode, which is an electrode arranged in a trench extending from the first surface 111 into the semiconductor layer 110. This, however, is only an example. It is also possible to implement the gate electrode as a planar electrode formed above the first surface 111. This is commonly known, so that no further explanation is required in this regard.

The source and body regions 43, 42 are connected to the first load terminal (source terminal) formed above the first surface 111. The first load terminal 52 is electrically insulated from the gate electrodes 44 of the transistor cells 40 by respective insulating layers 46.

According to one example, the transistor device is a superjunction transistor device. In this example, the transistor device further includes a plurality of compensation regions of the second doping type. The compensation regions 48 adjoin the drift region 47, so that PN junctions are formed between the compensation regions 48 and the drift region 47. The compensation regions 48 are connected to the first load terminal 52. For this, the compensation regions 48 may adjoin the body regions 42 that are connected to the first load terminal 52.

In addition to the drift region 47 and as explained above, the transistor device may include a drain region 41 connected to the second load terminal 53. The drain region 41 adjoins the drift region 47, for example. The drift region 47 is arranged between the drain region 41 and the body regions 42 and is spaced apart from the body regions 42 in the vertical direction of the die region 31. The vertical direction of the die region 31 equals the vertical direction of the semiconductor layer 130.

In a device of the type illustrated in FIGS. 12A-12B, each of the device regions except for the drain region 41 and the gate electrodes 44 indicates that electric 45 can be formed before removing the sacrificial layer 120. That is, the source and body regions 43, 42, the optional compensation regions 48, and the drift region 47 can be formed before removing the sacrificial layer 120. As explained above, the drain region 48 may be formed after removing the sacrificial layer 120 and partially removing the insulating layer 132 to uncover a portion of the second surface 112.

Referring to the above, the transistor device may be implemented as a MOSFET. In this example, the drain region 41 has the first doping type, which is the same doping type as the doping type of the source regions 43 and the drift region 47. According to another example, the transistor device is implemented as an IGBT. In this example, the drain region 41 has the second doping type, which is the same doping type as the body regions 42. In an IGBT, the drain region may also be referred to as collector region.

The transistor device can be implemented as an N-type (N-channel) or as a P-type (P-channel) transistor device. In an N-type device, the dopant atoms of the first doping type are N-type dopant atoms and the dopant atoms of the second doping type are P-type dopant atoms. In a P-type device, the dopant atoms of the first doping type are P-type dopant atoms and the dopant atoms of the second doping type are N-type dopant atoms.

The semiconductor layer 110 may have a basic doping of the first doping type. The source and body regions 43, 42, the optional compensation regions 48, and the drain region 41 may be formed by implantation processes in which dopant atoms of the respective device regions are implanted into the semiconductor layer, followed by an annealing process. In this example, a doping concentration of the drift region 47 equals the basic open concentration of the semiconductor layer 110. The basic doping concentration of the semiconductor layer 110 can be adjusted in the process of manufacturing the wafer 100.

In a vertical transistor device, a voltage blocking capability, which is the maximum voltage the transistor device can withstand between the first and second load terminals 52, 53 in the off-state, is essentially dependent on the doping concentration of the drift region 47 and the length of the drift region 47, which is the minimum distance between the drain region 41 and the body regions 42 in the vertical direction. Vertical dimensions of the body regions 42 and the drain region 41 are usually much smaller than the length of the drift region 47, so that the thickness of the semiconductor layer 110 mainly defines the length of the drift region 47. Given that the length of the drift region 47 defines the voltage blocking capability, exactly defining the thickness of the semiconductor layer 110 and, therefore, the vertical dimension of the die region 31, is a relevant aspect. This can be achieved by the method explained hereinabove.

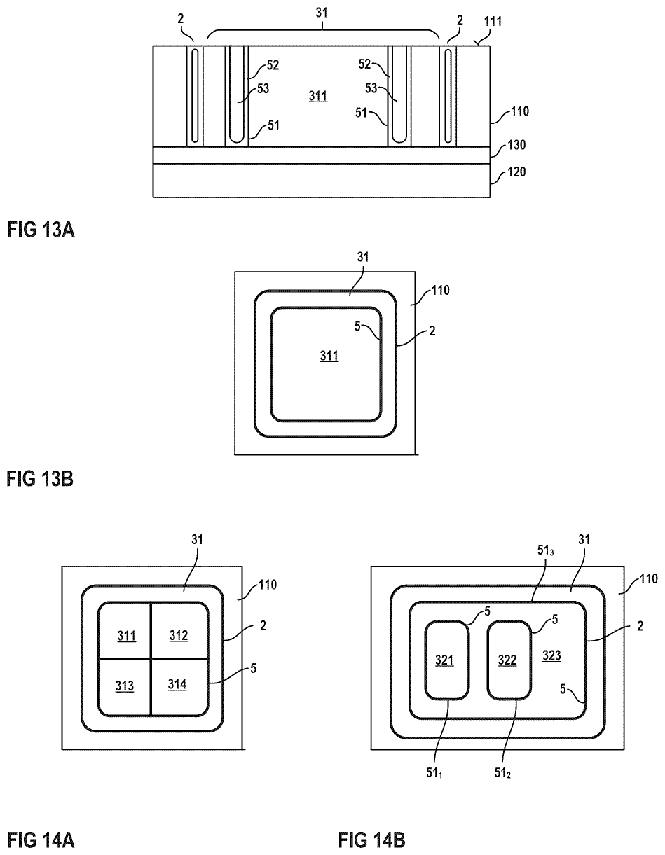

In the examples illustrated in FIGS. 7-12B, the die region 31 at the same time forms a device region for integrating a semiconductor device, such as a transistor device, therein. According to another example illustrated in FIGS. 13A-13B, a device region 311 for integrating a semiconductor device is a portion of the die region 31 surrounded by an isolation trench 51 of an isolation structure 5. FIG. 13A shows a vertical cross-sectional view of a die region 31 that includes a device region 311 surrounded by an isolation trench 51, and FIG. 13B shows a top view of the die region 31. In FIG. 13B, the separation structure 2 and the isolation structure 5 are schematically illustrated as bold lines. In FIG. 13A, the separation structure 2 and the isolation structure 5 are illustrated in greater detail.

The isolation structure 5, in in lateral directions, separates the device region 311 from further semiconductor regions of the die region 31. Referring to FIG. 13A, the isolation structure 5 includes the isolation trench 51 laterally surrounding the device region 311. The isolation structure 5 may further include a dielectric layer 52 covering sidewalls and a bottom of the isolation trench 51, and a filling layer 53 at least partially filling a residual trench or space defined by the dielectric layer 52 in the isolation trench 51. In the example illustrated in FIG. 13A, the filling layer entirely fills the residual trench.

According to one example, the insulating layer 52 is a dielectric layer of the same material as the dielectric layer 22 in the separation trench 21. According to one example, the dielectric layer 22 in the separation trench 21 and the insulating layer 52 in the isolation trench 51 are formed by the same process. This is explained in detail herein further below.

The filling layer 53 is an electrically insulating layer or an electrically conducting layer, for example. According to one example, the filling layer 53 is an electrically conducting layer and includes a polycrystalline semiconductor material, such as polysilicon.

In the example illustrated in FIGS. 13A-13B, one device region 311 surrounded by the isolation structure 5 has been formed in one die region 31. This, however, is only an example. Further examples are illustrated in FIGS. 14A-14B, which each illustrate a top view of a die region 31 according to one example. In each of the examples, the die region 31 includes several device regions.

In the example illustrated in FIG. 14A, the isolation structure 5 forms an isolating grid, wherein a device region 311, 312, 313, 314 is formed in each of the grid openings of the isolating grid.

In the example illustrated in FIG. 14B, the isolation structure 5 includes several isolation trenches that are spaced apart from each other. First and second isolation trenches 51₁, 51₂ each surround a respective portion of the die region 31 to form first and second device region 321, 322. A third isolation trench 51₃ surrounds a portion of the die region 31 that includes the first and second device regions 321, 322 so that the third isolation trench 51₃ in combination with the first and second isolation trenches 51₁, 51₂ forms a third device region 323, which is a portion of the die region 31 arranged between the first and second isolation trenches 51₁, 51₂ on one side and the third isolation trench 51₃ on the other side.

It should be noted that the examples illustrated in FIGS. 13B and 14A-14B are only 3 of a variety of different examples for forming device regions in the die region 31 using an isolation structure 5 having at least one isolation trench. Any combination of the examples illustrated in FIGS. 13B and 14A-14B is possible. In each case, an isolation trench surrounds a portion of the die region 31 to form a device region. In each case, the isolation structure 5 electrically insulates the individual device regions from each other.

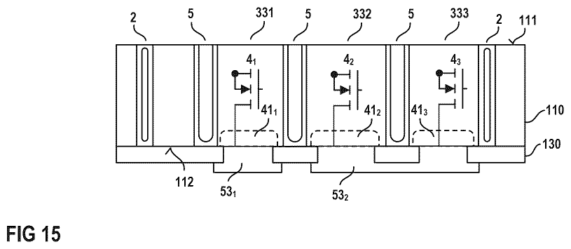

In each of the device regions a semiconductor device may be implemented. This is illustrated in FIG. 15 that shows a die region 31 that includes three different device regions 331, 332, 333 that are separated from each other by the isolation structure 5.

Just for the purpose of illustration, a vertical transistor device 4₁, 4₂, 4₃ having a second load terminal 53₁, 53₂ at the second surface 112 of the semiconductor layer 110 is integrated in each of the device regions 331, 332, 333. For the ease of illustration, first load terminals and control terminals of the transistor devices 4₁, 4₂, 4₃ are not illustrated in FIG. 15. These control terminals and first load terminals may be implemented in accordance with any of the examples explained herein before. According to one example, each of the transistor devices includes a drain region 41₁, 41₂, 41₃ adjoining the second surface 112 and connected to the respective second load terminal (drain terminal) 53₁, 53₂.

The semiconductor devices integrated in the individual device regions formed in the dire region 31 can be connected with each other in various ways by connecting terminals of the semiconductor devices s formed on top of the first and second surfaces 111, 112, such as the control and load terminals of transistor devices, with each other. However, this is only an example. According to another example, the semiconductor devices integrated in the device regions have separate terminals that are not connected with each other.

In the example illustrated in FIG. 15, transistor devices 4₂, 4₃ have their drain regions 41₂, 41₃ connected to the same drain terminal 53₂, while the further transistor device 4₁ has its drain region 41₁ connected to a separate drain terminal 53₁. In the same way, source regions (not illustrated) of two or more of the transistor devices 4₁, 4₂, 4₃ may be connected to the same source terminal and gate electrodes of two or more of the transistor devices 4₁, 4₂, 4₃ may be connected to the same control terminal (gate terminal).

Different types of electronic devices may be integrated in the same die 3 in different device regions. According to one example, only lateral devices are integrated in the same die 3. According to another example, only vertical devices are integrated the same die 3. According to yet another example, vertical devices and lateral devices are integrated in the same die 3.

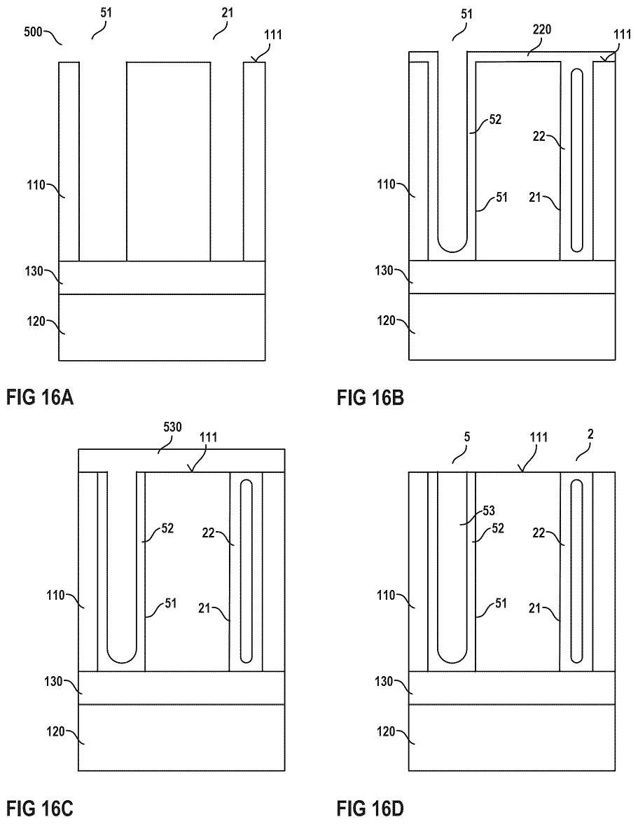

Referring to the above, the dielectric layer 22 of the separation structure 2 and the insulating layer 51 of the isolation structure 5 may be formed by the same process. One example of a method for forming the separation structure 2 and the isolation structure number 5 in this way is illustrated in FIGS. 16A-6D. Each of these figures shows a vertical cross-sectional view of one portion of the wafer during the manufacturing process.

FIG. 16A shows the wafer after forming one separation trench 21 and one isolation trench 51. According to one example, these trenches 21, 51 are formed by the same etching process using an etch mask (not illustrated in FIG. 16A). According to one example, the isolation trench 51 is wider than the separation trench 21. According to one example, a width of the isolation trench 51 is greater than 1.5 μm. According to one example, the width of the isolation trench 51 is at least 1.5 times, at least 2 times, or at least 3 times the width of the separation trench 21.

FIG. 16B shows the arrangement according to FIG. 16A after forming the dielectric layer 220. As explained above, the dielectric layer 220, in the separation trench 21, forms the dielectric layer 22 enclosing the void 23. In the isolation trench 51, the dielectric layer 220 covers sidewalls and a bottom and forms the insulating layer 52. Due to the isolation trench 51 being wider than the separation trench 21 formation of a void enclosed by the dielectric layer is avoided in the isolation trench 51.

As explained above, the method further includes removing the dielectric layer 220 from above the first surface 111. Furthermore, the method includes filling the residual trench, which remains in the isolation trench 51 after forming the insulating layer 52, with the filling material 53. Referring to FIG. 16C, filling the residual trench includes depositing a filling layer 530 after removing the dielectric layer 220 from above the first surface 111 such that the filling layer 530 fills the residual trench and covers the first surface 111. Furthermore, filling the residual trench includes removing the filling layer 530 from above the first surface 111. Referring to FIG. 16D, removing the filling layer 530 from above the first surface 111 includes, for example, a mechanical polishing process, a CMP process, an etching process, or a combination of two or more of these processes.

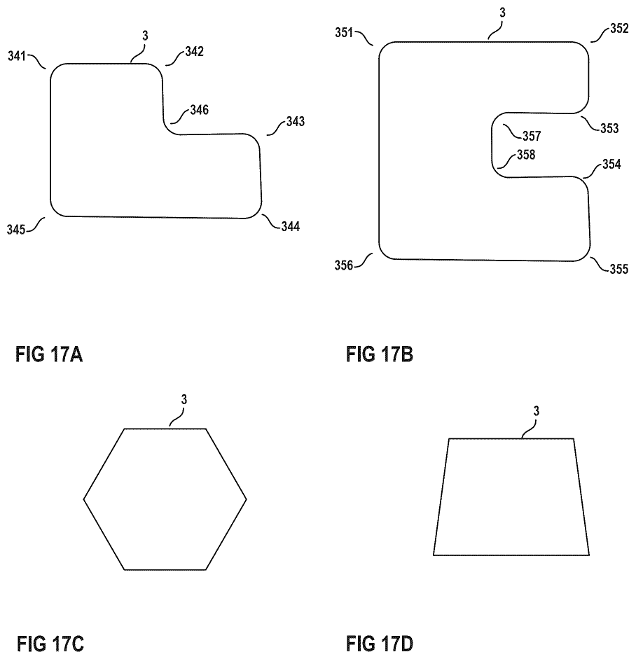

Referring to the above, the method explained before enables forming a semiconductor die 3 with a precisely defined thickness of the semiconductor layer included in the die 3. The geometrical shape of the semiconductor die 3 is defined by the shape of the separation structure 2 with the separation trench 21. Based on this, a variety of different geometrical shapes of the semiconductor die 3 different from a rectangular shape is possible. Just for the purpose of illustration, some possible shapes of the semiconductor die number 3 are illustrated in FIG. 13A-13D. Such geometrical shapes include, but are not restricted to, an L-shape as illustrated in FIG. 17A; a U-shape, as illustrated in FIG. 17B; a polygonal shape, such as a hexagonal shape as illustrated in FIG. 17C; or a hexagonal shape as illustrated in FIG. 17D. In each case, corners, if any are available, can be implemented as a rounded corners, as illustrated in FIGS. 17A and 17B, for example, or as sharp corners, as illustrated in FIGS. 17C and 17D, for example.

According to one example, the shape of the semiconductor die includes at least five corners, as illustrated in FIGS. 17A, 17C, and 17D for example. In the example illustrated in FIG. 17A, the L-shaped semiconductor die 3 includes six corners, five outwardly directed (outer) corners 341, 342, 343, 344, 345, and one inwardly directed (inner) corner 346. In the example illustrated in FIG. 17B, the U-shaped semiconductor die 3 includes eight corners, six outwardly directed (outer) corners 351, 352, 353, 354, 355, 356 and two inwardly directed (inner) corners 357, 358. This, however, is only an example. And a combination of outwardly directed (outer) and inwardly directed (inner) corners is possible.

According to one example, the shape of the semiconductor die number 3 includes at least 5 outwardly directed corners and at least one inwardly directed corner.

Some of the aspects explained above are briefly summarized in the following with reference to numbers examples.

Example 1. A method for forming a semiconductor die based on a wafer, the wafer comprising a semiconductor layer and sacrificial layer formed on opposite sides of an insulating layer, wherein the method comprises: forming a separation structure that comprises a separation trench laterally surrounding a die region in the first semiconductor layer of the wafer and that vertically extends from a first surface of the wafer through the semiconductor layer to the insulating layer of the wafer; removing the sacrificial layer; and detaching the die region along the separation structure to separate the semiconductor die from the wafer.

Example 2. The method according to example 1, wherein the separation structure further comprises a dielectric layer covering sidewalls and a bottom of the separation trench; and a void enclosed by the dielectric layer.

Example 3. The method according to example 2, wherein the dielectric layer comprises an oxide.

Example 4. The method according to any one of examples 1 to 3, wherein forming the semiconductor die further comprises: at least partially removing the insulating layer before detaching the die region.

Example 5. The method according to example 4, wherein at least partially removing the insulating layer includes maintaining portions of the insulating layer that adjoin the separation structure.

Example 6. The method according to any one of examples 1 to 5, wherein forming the semiconductor die further comprises: forming at least one semiconductor device in the die region before detaching the die region.

Example 7. The method according to example 6, wherein forming the at least one semiconductor device comprises: forming doped device regions in the die region before removing the second semiconductor layer.

Example 8. The method according to example 7, wherein forming the at least one semiconductor device further comprises: at least partially removing the insulating layer to uncover at least a portion of a second surface opposite the first surface of the first semiconductor layer; and forming an electrode adjoining the second surface.

Example 9. The method according to example 8, wherein forming the at least one semiconductor device further comprises: implanting dopant atoms for at least one further doped device region via the second surface into the die region before forming the electrode.

Example 10. The method according to any one of examples 1 to 9, wherein forming the semiconductor die further comprises: forming an isolation structure in the die region, wherein the isolation structure comprises an isolation trench laterally surrounding at least one device region in the die region and vertically extending from the first surface through the first semiconductor layer to the insulating layer.

Example 11. The method according to example 10, wherein the isolation structure further comprises: an insulating layer covering sidewalls and a bottom of the isolation trench; and a filling layer at least partially filling a space defined by the insulating layer in the isolation trench.

Example 12. The method according to example 11, wherein the filling layer comprises an electrically conducting material.

Example 13. The method according to any one of examples 6 to 12, wherein forming the at least one semiconductor device comprises forming the at least one semiconductor device in the at least one device region.

Example 14. The method according to any one of examples 10 to 13, wherein the separation trench and the isolation trench are formed by the same process.

Example 15. The method according to example 14, wherein the passivation layer of the separation structure and the insulating layer of the isolation structure are formed by the same process.

Example 16. The method according to any one of examples 1 to 15, wherein the sacrificial layer is a semiconductor layer.

Example 17. A semiconductor die having a shape different from a rectangular shape.

Example 18. The semiconductor die according to example 17, wherein the semiconductor die comprises at least five corners.

Example 19. The semiconductor die according to example 18, wherein the corners are rounded corners.

Example 20. The semiconductor die according to example 18 or 19, wherein the at least one five corners include at least five outer corners and at least one inner corner.

Example 21. The semiconductor die according to example 20, wherein the semiconductor die has an L-shape or a U-shape.

Example 22. The semiconductor die according to any of examples 17 to 21, wherein the semiconductor die comprises a dielectric layer covering sidewalls of the semiconductor die that form the shape of the semiconductor die.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A method for forming a semiconductor die based on a wafer, the wafer comprising a semiconductor layer and a sacrificial layer formed on opposite sides of an insulating layer, the method comprising:
forming a separation structure that comprises a separation trench laterally surrounding a die region in the first semiconductor layer of the wafer and that vertically extends from a first surface of the wafer through the semiconductor layer to the insulating layer of the wafer;
removing the sacrificial layer; and
detaching the die region along the separation structure to separate the semiconductor die from the wafer.

2. The method of claim 1, wherein the separation structure further comprises a dielectric layer covering sidewalls and a bottom of the separation trench, and a void enclosed by the dielectric layer.

3. The method of claim 2, wherein the dielectric layer comprises an oxide.

4. The method of claim 1, further comprising:
at least partially removing the insulating layer before detaching the die region.

5. The method of claim 4, wherein at least partially removing the insulating layer includes maintaining portions of the insulating layer that adjoin the separation structure.

6. The method of claim 1, further comprising:
forming at least one semiconductor device in the die region before detaching the die region.

7. The method of claim 6, wherein forming the at least one semiconductor device comprises:
forming doped device regions in the die region before removing the second semiconductor layer.

8. The method of claim 7, wherein forming the at least one semiconductor device further comprises:
at least partially removing the insulating layer to uncover at least a portion of a second surface opposite the first surface of the first semiconductor layer; and
forming an electrode adjoining the second surface.

9. The method of claim 8, wherein forming the at least one semiconductor device further comprises:
implanting dopant atoms for at least one further doped device region via the second surface into the die region before forming the electrode.

10. The method of claim 6, wherein forming the at least one semiconductor device comprises:
forming the at least one semiconductor device in the at least one device region.

11. The method of claim 1, further comprising:
forming an isolation structure in the die region,
wherein the isolation structure comprises an isolation trench laterally surrounding at least one device region in the die region and vertically extending from the first surface through the first semiconductor layer to the insulating layer.

12. The method of claim 11, wherein the isolation structure further comprises:
an insulating layer covering sidewalls and a bottom of the isolation trench; and
a filling layer at least partially filling a space defined by the insulating layer in the isolation trench.

13. The method of claim 11, wherein the separation trench and the isolation trench are formed by a same process.

14. The method of claim 13, wherein the passivation layer of the separation structure and the insulating layer of the isolation structure are formed by a same process.

15. A semiconductor die, comprising:
a semiconductor die region,
wherein the semiconductor die has a shape different from a rectangular shape.

16. The semiconductor die of claim 15, wherein the semiconductor die comprises at least five corners.

17. The semiconductor die of claim 16, wherein the at least five corners are rounded corners.

18. The semiconductor die of claim 16, wherein the at least one five corners include at least five outer corners and at least one inner corner.

19. The semiconductor die of claim 18, wherein the semiconductor die has an L-shape or a U-shape.

20. The semiconductor die of claim 15, further comprising:
a dielectric layer covering sidewalls of the semiconductor die region,
wherein the sidewalls define the shape of the semiconductor die.
